(19) United States
(12) Patent Application Publication
(10) Pub. No.: US 2024/0196749 A1
(43) Pub. Date: Jun. 13, 2024

(54) Process for the Fabrication of Zn-O Graphene Based Flexible Strain and Pressure Sensor

(71) Applicant: Council of Scientific and Industrial Research, New Delhi (IN)

(72) Inventors: Mousumi Majumder, Kolkata (IN); Swati Samanta, Kolkata (IN); Mousumi Baral Narjinary, Kolkata (IN)

(21) Appl. No.: 18/553,066

(22) PCT Filed: Mar. 24, 2022
(86) PCT No.: PCT/IN2022/050291

§ 371 Date: Sep. 28, 2023

(30) Foreign Application Priority Data
Mar. 31, 2021 (IN) 202111014941

(51) Int. Cl. H10N 30/077; H10N 30/02; H10N 30/06; H10N 30/081; H10N 30/092; H10N 30/30

(52) U.S. Cl. CPC H10N 30/077; H10N 30/02; H10N 30/06; H10N 30/081; H10N 30/092; H10N 30/302

(57) ABSTRACT

The present invention provides a process for the fabrication of a flexible strain and pressure sensor using a synergistic composition of ZnO nanoparticle and graphene nanoplatelets. The substrate used is PDMS, a polymer that imparts the desired properties of flexibility and durability to the sensor. The invention also discloses a simple and facile process of sensor fabrication, wherein the sensing element is embedded in the substrate material, and thereby prevents any deformation or peeling even after repeated stretch/release cycles. The reported flexible sensors can replace the conventional stiff sensors due to their ability to be contoured on curved surfaces, such as body parts. These sensors can find applications in wearable electronics and can have myriad of uses in healthcare monitoring, human-machine interface, electronic skin on prosthetics, and so on.

### FIELD OF THE INVENTION

The present invention relates to a process for the fabrication of ZnO-graphene based flexible strain and pressure sensors. The present invention particularly relates to the development of a flexible strain and pressure sensor. Present invention more particularly relates to the process of developing a flexible strain and pressure sensor by incorporating nano ZnO-graphene nanoplatelets on a polymeric substrate.

### BACKGROUND OF THE INVENTION

As a subdomain of wearable sensors, flexible strain sensors have garnered considerable attention owing to their conformability to curved and soft surfaces of the human body. Conventional metal foil-based strain gauges are not suitable for use as wearable sensors due to their low sensing range and poor flexibility. Excellent mechanical and electrical properties of metal nanowires, carbon nanotubes, graphene and nano semiconducting oxides have led to their wide use as functional sensing elements in wearable sensors. The properties of stretchability, conformity to curved regions, linearity and high sensitivity are closely associated to the satisfactory performance of wearable strain sensors. Simultaneously achieving all these properties in a single system often poses an engineering challenge. Thus, it has become imperative to develop wearable strain and pressure sensor systems that incorporate these desired features in optimum to allow their use in wide applications. Among the stretchable strain sensors, resistive gauges are widely used owing to their simple construction and convenient transduction techniques. Salient components in flexible/stretchable electronics include flexible strain and pressure sensors for use in wearable electronics, soft robotics, prosthetic devices, real-time remote health monitoring, etc. Some common examples are usage of these sensors as ECG sensors, pulse monitors, gait analysers, activity trackers, emotion detectors, kinetic sensors in gaming, etc.

Reference may be made to Patent No. WO2020197000AI, wherein a process for producing a flexible strain sensor has been proposed. The sensing material is formed of a nanocomposite comprising carbon nanotubes and metal nanoparticles, which is directly printed on a flexible substrate by the process of high-speed spraying and covered with another flexible cover. In this process, post treatments such as thermal-treatment or chemical-treatment are obviated.

Reference may be made to Patent No. KR2021004280A, wherein a self-healing flexible strain sensor has been presented. The active layer consists of graphene and magnetic iron oxide. Surface roughness of the polyurethane layer, which serves as the substrate, aids in better adhesion of the active layer on to it, thereby resulting in better durability and reliability of the designed strain sensors.

Reference may be made to Patent No. US20090301196AI, wherein piezoelectric and piezoresistive cantilever type sensors have been proposed. The sensing elements discussed are the piezoresistive carbon nanotubes and piezoelectric wurtzite II-VI compounds like zinc oxide. In the presence of a target substance, the functional layer undergoes a change in its electrical property, which is detected by the electrical sensor coupled to the electroactive cantilever.

Reference may be made to Patent No. IN2020311023739A, wherein a composite of PVDF and MWCNT has been used as a piezoresistive element to detect tremors in human limbs. The associated signal processing circuitry aids in the analysis of intensity, frequency and patterns of the body movements.

Reference may be made to Patent No. WO2013190398AI, wherein a process for the synthesis and use of graphene functionalized carbon nanotubes is presented. The composite nanofiller are further dispersed in a polymer matrix to form a flexible strain sensor.

Reference may be made to Patent No. IN 20191015175A, wherein a composite comprising 1D or 2D nano fills is functionalized with polymers such as PSS or PDDA to form an electromechanical strain sensor with gauge factor of at least 10. The flexible and water-resistant sensor is found to be suitable for use in wearable devices.

Reference may be made to Patent No. IN200704251P2, wherein the design of a flexible strain sensor consisting of polymide and carbon black is proposed. The sensor can be used to detect strain in extension, compression and tension.

Reference may be made to Patent No. US20110006286A1, wherein a flexible sensor to detect transverse force, pressure and vibration has been proposed. The piezoelectric zinc oxide nanostructure provides the strain sensitivity and the PDMS provides the desired flexibility.

Reference may be made to Patent No. US20080067618A1 (Assignee: Georgia Tech Res Inst) wherein piezoelectric zinc oxide nanowires are deposited on a polymer substrate and are made to undergo a deformation by an attached structure, thereby generating the piezoelectric properties in the nanowires.

Reference may be made to Patent No. GB201612179D0, wherein a piezoresistive element-based strain sensor is used as a flow sensor to detect the flow of breast milk. The strain gauge may be connected in quarter, half or full Wheatstone bridge configuration to measure strain under tension and compression.

The flexible material incorporated in the sensor is polymide, which helps in easy contouring on the skin. The device has an inbuilt memory and can be operated in wireless mode.

Reference may be made to Patent No. KR2015002972A, wherein metallic and semiconducting carbon nanotubes are proposed as bipolar strain sensing elements in a flexible train sensor. The sensor is capable of measuring the direction and amplitude of the applied strain. In another application, these sensors may be used as chemical sensors to detect the presence and concentration of certain chemicals.

Reference may be made to Patent No. CN106441646A, wherein the use of carbon nanotubes in flexible pressure sensors is proposed. It combines the micro-nano processing techniques with printed electronics technology to realise polymer substrate-based pressure sensors in Wheatstone bridge configuration.

Reference may be made to Patent No. CN104614101A, wherein single walled carbon nanotubes have been employed as the active FET channel material and incorporating the same in a flexible piezoelectric strain/pressure sensor.

Reference may be made to Patent No. CN106883586A, wherein a process for the preparation of an adjustable strain sensor is proposed. It is based on a composite of nano-conductive material and shape memory polymer. The nano conductive materials include metals such as silver nanowire, gold nanowire, copper nanowire and nanometre carbon materials, such as SWCNT, GO, etc. The composition of the hybrid material is: 1-5 parts of the nanometre conductive material and 99-95 parts of the polymer material.

Reference may be made to Patent No. CN102315381A, wherein the use of a composite of zinc oxide nanofilm and carbon fibres is proposed in a gas pressure sensor of automobiles or in the pneumatic pressure sensors in an aircraft engine.

Reference may be made to prior art literature ‘Flexible zinc oxide nanowire array/graphene nanohybrid for high-sensitivity strain detection’ (ACS Omega, Mohan Panth et al, 2020) wherein a flexible strain sensor comprising vertically aligned ZnO nanowire and graphene has been proposed. The ZnO nanowires were grown by a seedless hydrothermal process. Under mechanical loading, the ZnO nanowires produced a piezoelectric gate potential on the conductance of the graphene channel, which gives a measure of the induced strain. The sensor exhibited good dynamic response with a response time of 0.2 s. Besides, under bending forces, the sensor showed a gauge factor of 248.

Reference may be made to literature ‘Ink-jet printed stretchable strain sensor based on graphene/ZnO composite on micro-random ridged PDMS substrate’ (Composites Part A, Gul Hassan et al, 2018) wherein a flexible strain sensor based on graphene-ZnO nanocomposite is presented. Zinc oxide acts as nanofillers and increase the connectivity of the adjacent graphene flakes. The tensile stretchability and bending diameter measured for this sensor were found to be 30% and 1 cm. respectively.

Reference may be made to literature ‘Strain sensing skin-like film using zinc oxide nanostructures grown on PDMS and reduced graphene oxide’ (Structural Monitoring and Maintenance, Tejus Satish et al, 2017) wherein a composite of reduced graphene oxide and ZnO nanorods is used as the sensing element on a polymeric substrate. The sensor responds well to cyclic strain and is found to be suitable for applications as a strain sensing electronic skin.

Reference may be made to literature ‘Wearable piezoresistive strain sensor based on graphene-coated three-dimensional micro-porous PDMS sponge’ (Micro and Nano Systems Letters, Young Jung et al, 2019) wherein a flexible piezoresistive strain sensor based on graphene-coated porous PDMS is presented. Pores are introduced in the PDMS sponge by sugar templating process and subsequently graphene-ink is deposited by dip-coating process. The strain sensors thus fabricated exhibited stable mechanical properties till 60% elongation, good sensitivity of 19.2 and had repeatable piezoresistive response till 1000 cycles.

Reference may be made to literature ‘A wearable strain sensor based on the ZnO/graphene nanoplatelets nanocomposite with large linear working range’ (Electronic Materials, Shibin Sun et al, 2019) wherein a nanocomposite comprising zinc oxide nanoparticles and graphene nanoplatelets was used as the sensing element in a flexible strain sensor. The sensor showed wide working range (0-44%), high gauge factor (8.8-12.8), and excellent linearity (R2=0.999) and is proposed to be suitable for use in wearable devices. Reference may be made to literature ‘Flexible piezotronic strain sensor’ (Nanoletters, Jun Zhou et al, 2008) wherein piezoelectric ZnO nanowire-based strain sensor has been proposed. The current-voltage characteristics of the nanowire are observed to be dependent on the Schottky-barrier height, which is turn linearly dependent on the applied strain. Variation in the Schottky barrier height is governed by the change in band structure and the associated change in piezoelectric effect of the ZnO nanowire. The experimental data was well explained by the thermionic emission-diffusion theory. A gauge factor of 1250 has been reported.

Reference may be made to literature ‘High strain sensors based on ZnO nanowire/polystyrene hybridised flexible films’ (Advanced Materials, Xu Xiao et al, 2011) wherein axially grown nanowires of zinc oxide on polystyrene formed the sensing element of the flexible strain sensor. The sensor is reported to have a gauge factor of 116 and a measuring range of 50% and response tie of 140 ms. Further, a solar cell with open circuit voltage of 3.7 V under 1.5 sun illumination was used to power the sensor in outdoor configuration, thereby indicating the use of these sensors in outdoor conditions.

The inventions disclosed in prior arts above use of graphene-coated porous sponge as a strain sensing element in a flexible strain sensor. Deposition of graphene on the polymer substrate was done by dip coating process. This process does not include nano zinc oxide as the filling material. However, the present invention combines the piezoresistive graphene nanoplatelets with the filler ZnO nanoparticles in order to improve the connectivity between the flakes of graphene.

Further the inventions disclosed in prior arts describe the use of graphene-ZnO composite on ridged PDMS substrate as a strain sensing element. The process of ink-jet printing, which is used for the deposition of the nanocomposite, is a costly one and may have limited use in mass production of the sensors due to the high cost of the equipment. However, the present invention uses a very facile and cost-effective technique for the deposition of the sensing element. The step of spin-coating followed by peeling of the polymeric substrate is both cost-effective and time-saving, and hence suitable for mass production of the sensors. Prior art reveals the use of zinc oxide nanowire/graphene nanohybrid for strain detection. In this technique, monolayer graphene was grown by CVD process and transferred onto a PET substrate by elaborate and very precise transfer techniques. Electrode deposition was done by electron beam evaporation. Subsequently, vertically aligned nanowires of ZnO were grown at 90° C. for 4h, under strictly controlled pH value of the precursor solution. Thus, the fabrication steps require very precise control of the process parameters at each step. The present invention, on the other hand, uses very simple and scalable fabrication steps thereby making it suitable for mass production of the strain sensors.

Prior art discloses the use of silver nanowires as the strain sensing element in a polymer-composite flexible strain sensor. Silver nanowires were grown by the modified polyol process. The sensor fabrication work reports a facile synthesis technique using the peeling process. While the strain sensor reports a wide measurement range up to 70% stretchability, the gauge factors are moderate, 2-14. However, the present invention reports improved gauge factor, which indicates the suitability of application of these sensors in area demanding higher strain sensitivity.

Further prior art disclosed the use of ZnO nanostructures-reduced graphene oxide composite as the sensing element on a PDMS substrate for use as a strain sensing film. While the piezoresistive zinc oxide is responsible for the strain sensing, reduced graphene oxide helps to improve the connections between the ZnO clusters and thus enhance the strain sensitivity. However, this process involves the deposition of a layer of zinc on the PDMS substrate, using sputter coating, for the intended purpose of Zn seeding. This additional step is costly and not required in the present invention.

Thus, keeping in view the drawbacks of the hitherto reported prior arts, the present invention deals with the development of a facile fabrication process that can be employed to fabricate a flexible strain and a pressure sensor wherein ZnO nanoparticles-graphene nanoplatelets composite serves as the sensing element. Present invention relates to polydimethylsiloxane (PDMS) as the polymeric matrix for the ZnO-graphene composite sensor. PDMS is a highly elastic and dielectric elastomer, which lends the essential flexibility to the sensor. The strain sensitivity of the sensor is attributed to the piezoresistive property of ZnO-graphene composite. The single usage of ZnO as the sensing element encountered low conductivity issues due to the non-contiguous dispersion of the ZnO in the polymer matrix; whereas graphene used alone resulted in linearity over a very small measurement range.

Herein, present invention claimed a flexible strain sensor and a pressure sensor comprising a PDMS substrate, on which is coated a composite sensing layer consisting of nano ZnO and graphene nanoplatelets. The ZnO-graphene composite endows the sensor with the desired properties of high sensitivity and superior linearity in a wide measurement range. The strain sensitivity of the composite sensor is expressed in terms of its gauge factor.

### Objective of the Invention

The main objective of the present invention is to provide a process for the fabrication of ZnO-graphene based flexible strain and pressure sensor, which obviates the drawbacks of the hitherto known prior art as detailed above.

Another objective of the present invention is to provide a process for using a composite of ZnO nanoparticles and graphene nanoplatelets as the sensing element and PDMS as the flexible and durable substrate material of the strain and pressure sensors.

Another objective of the present invention is to provide a flexible strain sensor to replace the conventional stiff sensors that are required to be used in strain monitoring on contoured or curved surfaces.

Yet another objective of the present invention is to provide a simple and cost-effective process for the fabrication of sensors wherein the sensing element is securely embedded in the substrate and does not undergo adherence issues after several stretch/release cycles.

Further objective of the present invention is to provide a flexible strain sensor with a high gauge factor and a wide measurement range.

Further objective of the present invention is to provide a flexible pressure sensor with a high sensitivity and a wide measurement range.

Yet another objective of the present invention is to provide a flexible sensor wherein the substrate and the sensing elements have been chosen to be biocompatible in nature, in order to indicate their usage in wearable sensors.

Still another objective of the present invention is to provide a flexible strain sensor that could have numerous applications as electronic skin, in robotics, biomechanics, prosthetic skin, health monitoring, etc.

### SUMMARY OF THE INVENTION

Piezoresistive strain and pressure sensors respond to mechanical stimuli by the change in their electrical resistances. Two main desirable criteria of strain and pressure sensors are high sensitivity as well as wide measuring range. Recently, there has been an increase in interest about flexible pressure and strain sensors due to their varied application areas, such as remote human health monitoring, biomechanics for sports and video gaming, structural health monitoring, etc.

In an embodiment of the present invention, provides highly flexible pressure and strain sensors with superior sensitivity and large measuring range using nano ZnO-graphene based polymeric sensors. Synergistic ratios of ZnO nanoparticles and graphene nanoplatelets are used as the active sensing elements, while PDMS serves as the flexible substrate. Unlike the commonly used process which employ direct coating steps such as sputtering, CVD, electrochemical deposition, etc. on substrates, the present process involves a unique peel-off technique for sensor deposition. Electrodes are deposited by using silver paste. Finally, a layer of PDMS is coated as a top passivation layer; thereby sandwiching the sensing element between two layers of PDMS. Main advantages associated with this process are the high sensitivity and wide measurement range of the sensors, and superior adhesion between the substrate and sensing layers, resulting in no deformation or peeling of the coating layer.

Accordingly the present invention provides a process for the fabrication of ZnO-graphene based flexible strain and pressure sensor which comprises preparation of a synergistic mixture of ZnO nanoparticles and graphene nanoplatelets with polyurethane in suitable solvents, followed by spin coating and curing on a glass substrate as per stated recipe and further spin coating and curing by a first layer of PDMS, followed by subsequent peeling step leading to an embedded sensing layer, connecting copper terminals to the embedded sensor using silver epoxy, and adding a final passivation layer of PDMS on the embedded sensor.

In an embodiment of the present invention, ZnO nanoparticles with average particle size distribution of 207.1 nm within a range of 43.8 to 712 nm were selected.

In another embodiment, graphene nanoplatelets with average particle size distribution of 105.2 nm within a range of 50.7 to 220 nm were selected.

In yet another embodiment a synergistic mixture of ZnO nanoparticles and graphene nanoplatelets in varying ratios of 0.5:1, 1:1 and 1:0.5, respectively, were prepared in N-Methyl-2-pyrrolidone (NMP).

In yet another embodiment, polyurethane (PU) dissolved in dimethylformamide (DMF) was added to the ZnO-graphene ink to yield the final precursor for the sensing layer.

In yet another embodiment, viscosity of the precursor ink was found to be in the range of 14-15 mPa-s.

In yet another embodiment, polydimethylsiloxane (Sylgard), an elastomeric base and curing agent is thoroughly mixed in the ratio 10:1 and degassed till bubble-free and was used as the two layers in sandwiching the active sensing layer.

In yet another embodiment, the Modulus value of the cured PDMS substrate material was found to be in the range of 1.5-2.5 MPa.

In yet another embodiment, the process for the fabrication of ZnO-graphene based flexible pressure sensor is described as comprising the following steps:
a) ZnO-graphene mixtures in above-stated ratios, along with PU were mixed and further sonicated for 30 min. at room temperature to reach an optimum viscosity of 14.5 mPas.
b) A glass slide (25×25 mm²) was masked with scotch tape to leave an exposed section of 15×2 mm² at the centre.
c) 20 μl of the ZnO-graphene ink was dispensed on the exposed window of the substrate using a micropipette and the solution was spin coated at a speed of 250 rpm, acceleration time of 60s and control time of 60 s, followed by heating at 60° C. for 10 min. on a hot plate. This step was repeated thrice.
d) The masking tapes were removed from the glass slide and the PDMS solution was spin coated over the ZnO-graphene pattern at 100 rpm, acceleration time of 5s and control time of 300s to yield a PDMS layer of approximate 0.4 mm thickness which was then heated at 100° C. for 2 min.
e) After curing, the PDMS layer was peeled from the glass slide, and in the ensuing process, the ZnO-graphene layer got completely transferred on to the PDMS layer.
f) Cu wires were fixed to the two ends of the embedded sensing thin film by silver paste for further electrical measurements.
g) a layer of PDMS was poured on the embedded ZnO-graphene to form a sandwich structure of the pressure sensor and was cured at 80° C. for 10 min to act as the passivation layer.

In yet another embodiment, the process for the fabrication of ZnO-graphene based flexible strain sensor is described as comprising the following steps:
a) ZnO-graphene mixtures in above-stated ratios, along with PU were mixed and further sonicated for 30 min. at room temperature to reach an optimum viscosity of 14.5 mPas.
b) A glass slide (75×25 mm²) was masked with scotch tape to leave an exposed section of 50×5 mm² at the centre.
c) 100 μl of the ZnO-graphene ink was dispensed on the exposed window of the substrate using a micropipette and the solution was spin coated at a speed of 250 rpm, acceleration time of 60s and control time of 60 s, followed by heating at 60° C. for 10 min. on a hot plate. This step was repeated thrice.
d) The masking tapes were removed from the glass slide and the PDMS solution was spin coated over the ZnO-graphene pattern at 100 rpm, acceleration time of 5s and control time of 300s to yield a PDMS layer of approximate 0.4 mm thickness which was then heated at 100° C. for 2 min.
e) After curing, the PDMS layer was peeled from the glass slide, and in the ensuing process, the ZnO-graphene layer got completely transferred on to the PDMS layer.
f) Cu wires were fixed to the two ends of the embedded sensing thin film by silver paste for further electrical measurements.
g) a layer of PDMS was poured on the embedded ZnO-graphene to form a sandwich structure of the strain sensor and was cured at 80° C. for 10 min to act as the passivation layer.
h) In still another embodiment of the present invention, the pressure sensor having composition 1:0.5::ZnO:graphene showed the highest sensitivity of 8.72×10⁻⁴ in the range of 0-250 KPa with a linearity of 0.934.

In still another embodiment of the present invention, the strain sensor having composition 1:0.5::ZnO:graphene showed the highest gauge factor of 196.03 in the range of 0-0.10 strain (mm/mm) with a linearity of 0.940.

In still another embodiment of the present invention, the strain sensor having composition 1:1::ZnO:graphene showed a bending angle response of 0.02/degree of bending.

In still another embodiment of the present invention, a simple and cost-effective process for the fabrication of strain and pressure sensors is reported. Notably, the sensing layer remains completely embedded in the substrate even after several stretch/release cycles and there are no visible signs of peeling, buckling, etc. of the sensing layer.

### BRIEF DESCRIPTION OF THE DRAWINGS

The invention has other advantages and features which will be more readily apparent from the following detailed description of the invention and the appended claims, when taken in conjunction with the accompanying drawings, in which:

FIG. 1 represents the schematic diagram of the strain/pressure sensor. The ZnO-graphene layer forms the active sensing element. Silver electrodes are established at the two terminal points of the sensing zone. Two layers of PDMS serve as the substrate and top covering of the sensor.

FIG. 2 represent Measurement of bending angle

FIG. 3 represent SEM micrograph of Graphene nanoplatelets

FIG. 4 represent SEM micrograph of ZnO nanoparticles

FIG. 5 represent XRD pattern of graphene nanoplatelets

FIG. 6 represent XRD pattern of ZnO nanoparticles

FIG. 7 represent Particle size distribution of graphene nanoplatelets

FIG. 8 represent Particle size distribution of ZnO nanoparticles

FIG. 9 represent viscosity profile of precursor ink containing ZnO:Gr in 1:0.5 ratio

FIG. 10 represent tensile stress/strain response of PDMS

FIG. 11 represent tensile strain sensitivity measurement setup

FIG. 12 represent Strain sensitivity plot of 0.5:1 ZnO:graphene composite sensor

FIG. 13 represent Strain sensitivity plot of 1:1 ZnO:graphene composite sensor

FIG. 14 represent Strain sensitivity plot of 1:0.5 ZnO:graphene composite sensor

FIG. 15 represent Pressure sensitivity measurement setup

FIG. 16 represent Pressure sensitivity plot of 0.5:1 ZnO:graphene composite sensor

FIG. 17 represent Pressure sensitivity plot of 1:1 ZnO:graphene composite sensor

FIG. 18 represent Pressure sensitivity plot of 1:0.5 ZnO:graphene composite sensor

FIG. 19 represent Bending angle sensitivity plot of 1:1 ZnO:graphene composite strain sensor

### DETAIL DESCRIPTION OF THE INVENTION

While the invention has been disclosed with reference to certain embodiments, it will be understood by those skilled in the art that various changes may be made and equivalents may be substituted without departing from the scope of the invention. In addition, many modifications may be made to adapt to a particular situation or material to the teachings of the invention without departing from its scope.

Throughout the specification and claims, the following terms take the meanings explicitly associated herein unless the context clearly dictates otherwise. The meaning of “a”, “an”, and “the” include plural references. The meaning of “in” includes “in” and “on.” Referring to the drawings, like numbers indicate like parts throughout the views. Additionally, a reference to the singular includes a reference to the plural unless otherwise stated or inconsistent with the disclosure herein. In line with the above objectives. The present invention relates to the process for the fabrication of ZnO-graphene based flexible strain and pressure sensor, which has a fairly linear response within the measurement range. The invention also discloses the step-by-step sensor fabrication steps and provides an explanation of the sensing mechanism. For the pressure sensor fabrication, a mixture of ZnO nanopowder and graphene nanoplatelets in different proportions was prepared in a solution of NMP and polyurethane (PU) dissolved in DMF was added and mixed together at 400 rpm to yield a uniform ZnO-graphene ink. In the next step, a glass substrate (25×25 mm²) was masked with scotch tape to leave an exposed section of 15×2 mm² at the centre. 20 μl of the sensing ink was dispensed on the exposed window of the substrate using a micropipette and the solution was spin coated at a speed of 250 rpm for 60 s, followed by heating at 60° C. for 10 min. on a hot plate. The heating step was essential for proper curing of the ink as well as for increasing its electrical conductivity by removal of the solvents. This step was iterated thrice. The masking tapes were removed at this stage and a PDMS solution (10:1) was spin coated on the glass substrates containing the preheated ZnO-graphene pattern at 100 rpm for 300s to yield a PDMS layer of approximate 0.4 mm thickness and heated at 100° C. for 2 min. Subsequently the cured PDMS was peeled from the glass substrate, whereby the ZnO-graphene layer gets completely transferred on to the PDMS layer. Cu wires were fixed to the two ends of the embedded sensing thin film by silver paste for further electrical measurements. Finally, another layer of PDMS was poured on the embedded ZnO-graphene to form a sandwich structure of the strain sensor and cured at 80° C. for 10 min for passivation.

For the strain sensor fabrication, a glass substrate (75×25 mm²) was masked with scotch tape to leave an exposed section of 50×5 mm² at the centre. 100 μl of the sensing ink was dispensed for spin coating on the exposed section. Other fabrication steps are identical to those of the pressure sensor discussed above.

Novelty of this invention is to demonstrate a facile process of graphene-ZnO based sensor fabrication for making the composite structure very robust without the involvement of any instrumental technique. In general, the hydrophobic surface of PDMS requires elaborate surface preparation process, such as oxygen plasma etching, in order to increase its surface energy for a firm, adherent deposition of the sensing film. Whereas, in our process, by casting the liquid PDMS on the graphene-ZnO film, we allow the PDMS to enter into the network structure of pores of the sensing film. The low viscosity and low surface energy of the polymer aid in its movement within the interconnected porous network. Upon curing of the polymer and its subsequent peeling from the substrate, we observe a neat transfer of the sensing film onto the polymer, wherein the graphene-ZnO nanocomposite is evenly embedded on the PDMS surface with excellent adhesion. Thus, this fabrication process helps in surpassing the commonly reported problems of poor adhesion and surface wrinkling, buckling or tearing of the sensing film upon repeated mechanical loading/unloading cycles.

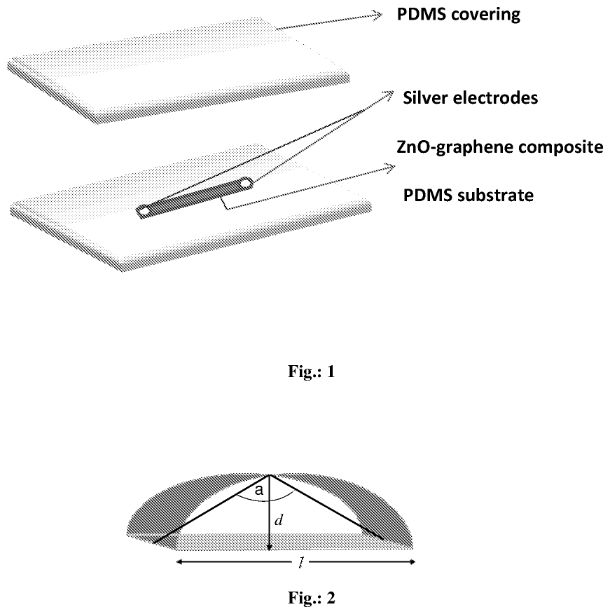

The present invention is illustrated in FIG. 1 of the drawing accompanying this specification. In the drawings like reference numbers/letters indicate corresponding parts in the various figures.

The strain sensitivity test of the strain sensors was carried out on a Newport translational stage using a motion controller with precision of 0.1 μm. The sensor was mounted on the translation stages and subjected to stretch-release cycles, while the resistance changes were measured using a voltmeter (Agilent 3458A). For pressure-sensitivity measurements, the sensors were subjected to a normal force using a force gauge (Lutron, FG-5000A). The change in relative resistance of the strain sensor, per unit strain is measured in each case and is defined as the sensitivity, or gauge factor of the strain sensor; while the change in relative resistance per unit pressure is defined as the pressure sensitivity. For bending angle measurement, an in-house fabricated jig was used to produce the desired angles of flexion between 20 to 900 to the composite strain sensors. The angle of flexion, a, is calculated from the following equation α=2 arctan(0.5l/d)

Corresponding resistance measurements were recorded at different angles of flexion (FIG. 2).

### Scientific Explanation, Novelty and Non-Obvious Inventive Steps

ZnO, being a wurtzite semiconducting metal oxide, is reported to possess high strain and pressure sensitivity and is a suitable candidate for strain and pressure sensors. However, ZnO-based strain and pressure sensors are limited by the useful working range. In order to combine the advantages of high sensitivity and large operating range, a synergistic mixture of ZnO and graphene nanoplatelets has been proposed in this work. The graphene nanoplatelets provide interconnections between the ZnO nanoparticle clusters thereby providing conducting pathways between them. Thus, the pressure and strain sensors fabricated from these synergistic compositions show high sensitivity and large linear working ranges. PDMS, on the other hand possesses excellent mechanical properties and lend the requisite flexibility to the sensors, when used as the substrate and passivation layers.

Deposition techniques using complicated vapor deposition techniques, viz PVD/CVD, lithographic techniques, etc. have been reported by other researchers, but not used by us. We have used a facile, economical and scalable process for fabrication of the sensors, viz. by peel-off technique. We have used a facile process, by peel-off technique of the PDMS, which results in a very good adhesion of the sensing film, as it gets partially embedded in the polymer matrix. This helps in proper adhesion of the film on the substrate and gets rid of the problems such as wrinkling or delamination, when exposed to several repeated loading-unloading cycles. Besides, the process is much more cost-effective than CVD, plasma treatment, lithography and inkjet printing.

### EXAMPLES

The following examples, which include preferred embodiments, will serve to illustrate the practice of this invention, it being understood that the particulars shown are by way of example and for purpose of illustrative discussion of preferred embodiments of the invention.

### Example-1

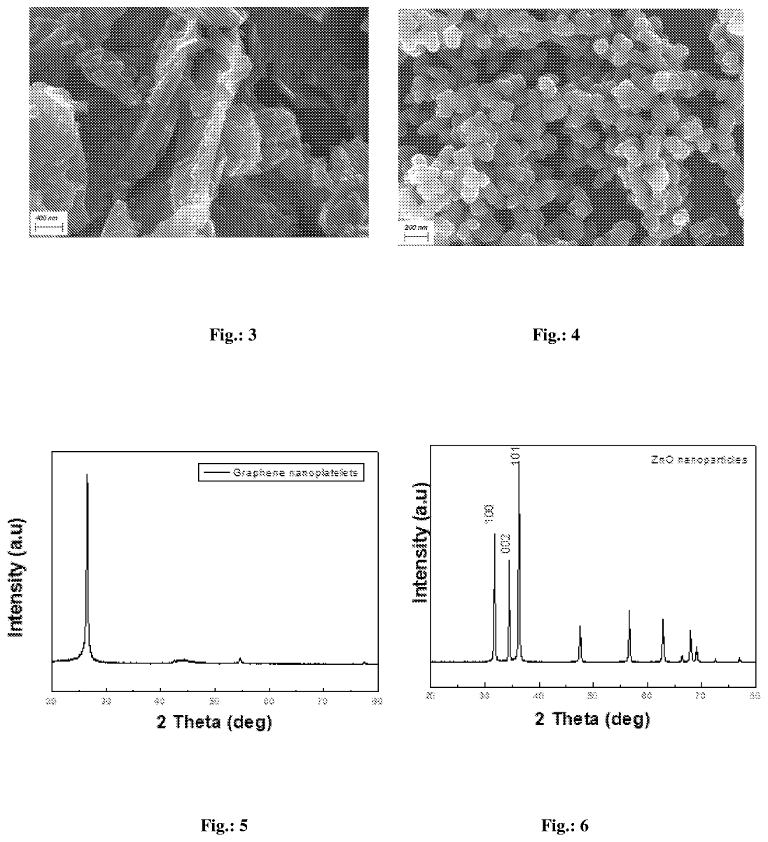

Morphological and structural characterization of the constituents of the active sensing element Microstructural properties of the two main constituents of the sensing element, viz. graphene nanoplatelets and zinc oxide nanoparticles were analysed by field emission scanning electron microscopy (FESEM). FIG. 3 shows aggregates of graphene platelets with average thickness of a few nm. The average particle size of the hexagonal nanoparticles of ZnO is around 93 nm (FIG. 4). The structural properties of the constituents were investigated by X-ray diffraction (XRD) studies using Cu Kα radiation. FIG. 5 shows the XRD pattern of graphene with a sharp peak at 26.5°. FIG. 6 confirms the wurtzite phase of ZnO with the characteristic peaks.

### Example-2

### Particle Size Distribution

Dispersions of graphene and ZnO were prepared separately in DI water and sonicated for 5 min. Size distribution of the dispersions were determined by the Dynamic Laser Scattering (DLS) process.

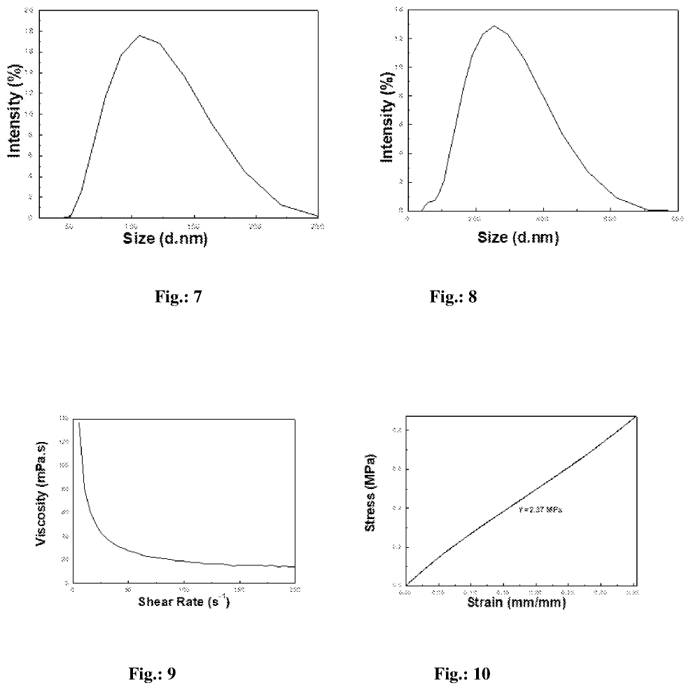

Graphene nanoplatelets were found to have an average hydrodynamic diameter value of 105.2 nm within a range of 50.7 to 220 nm (FIG. 7) and ZnO nanoparticles that of 207.1 nm within a range of 43.8 to 712 nm (FIG. 8).

### Example-3

### Rheological Properties of the Precursor Solution

A mixture of ZnO nanopowder and graphene nanoplatelets in a ratio of 1:0.5 was prepared in a solution of NMP and polyurethane (PU) dissolved in DMF was added and mixed together at 400 rpm to yield a uniform ZnO-graphene ink. Prior to using this ink for spin coating, its rheological properties are studied at room temperature under controlled shear rate. The corresponding flow characteristics are shown in FIG. 9 and a viscosity value of 14.5 mPa-s is recorded.

### Example-4

### Tensile Properties of the Base Polymer (PDMS)

Tensile testing of the PDMS substrate was carried out in a Universal Testing Machine at ambient conditions of temperature (25° C.) and relative humidity (63%). All samples were tested in triplicate and the average value has been reported. Each test coupon dimension was 285×21×1.5 mm. Gauge length was 28 mm and cross-head speed fixed at 25 mm/min. The stress-strain response was observed to be linear with a modulus value of 2.37 MPa. Maximum strain value in linear range recorded was 35% (FIG. 10).

### Example-5

### Strain Response of the Composite Sensors

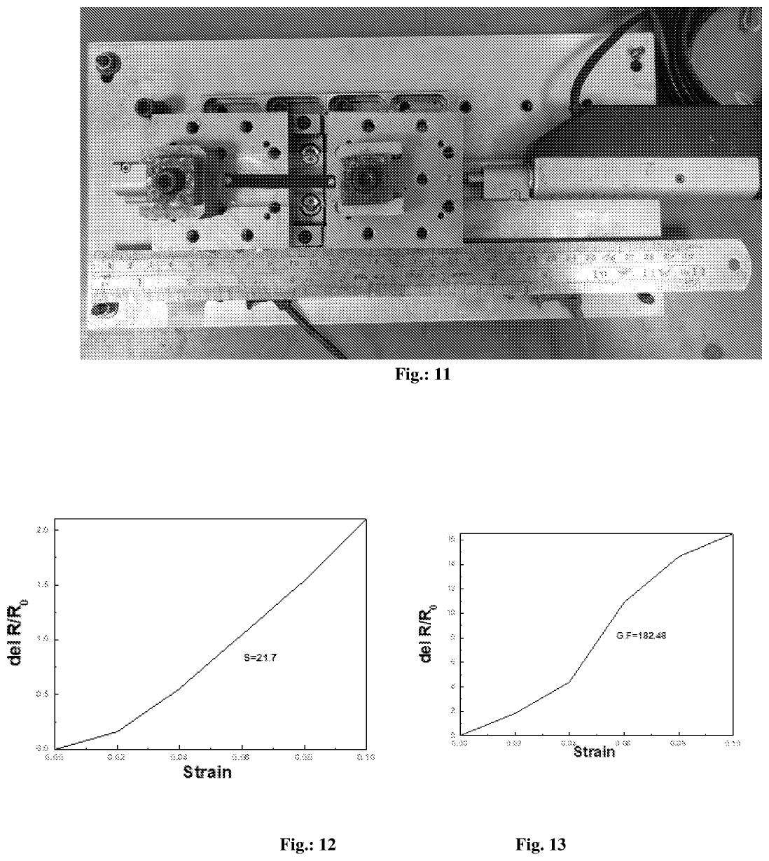

For the measurement of tensile stress-strain curves of the polymeric composite sensors, an arrangement for linear stretching (Newport) comprising one fixed stage and one translational stage was used as shown in FIG. 11. The sensor is held between the two stages and stretched linearly. Corresponding change in its electrical resistance was measured with an Agilent-make multimeter. Strain sensitivity curves of the three sensors are plotted in FIGS. 12-14 and gauge factors of the sensors are calculated from the respective slopes of the sensitivity curves.

### Example-6

### Pressure Response of the Composite Sensors

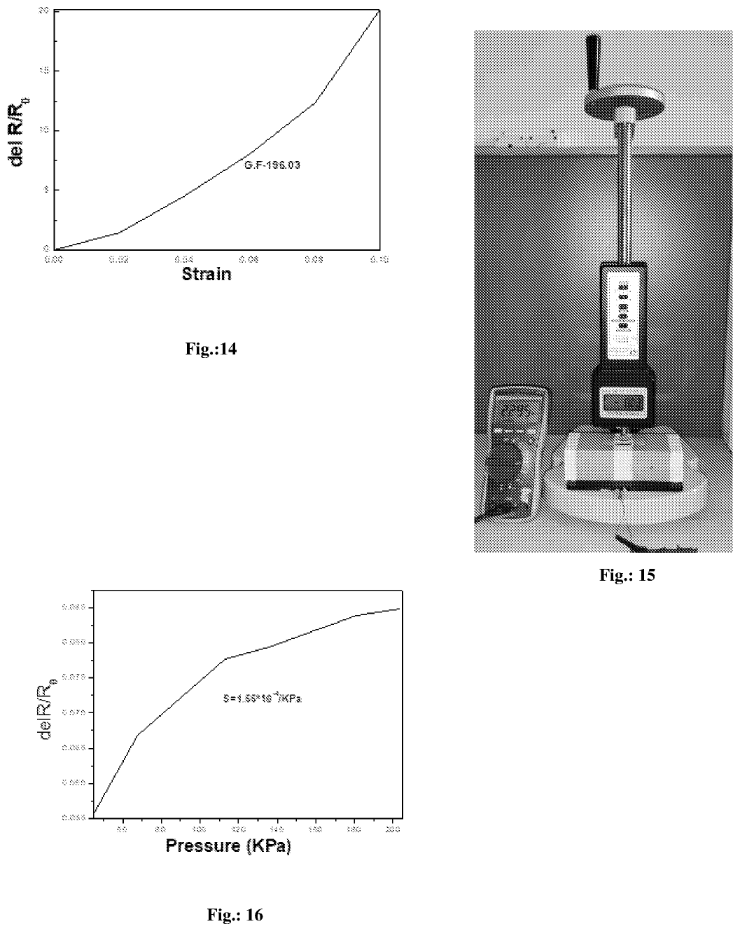

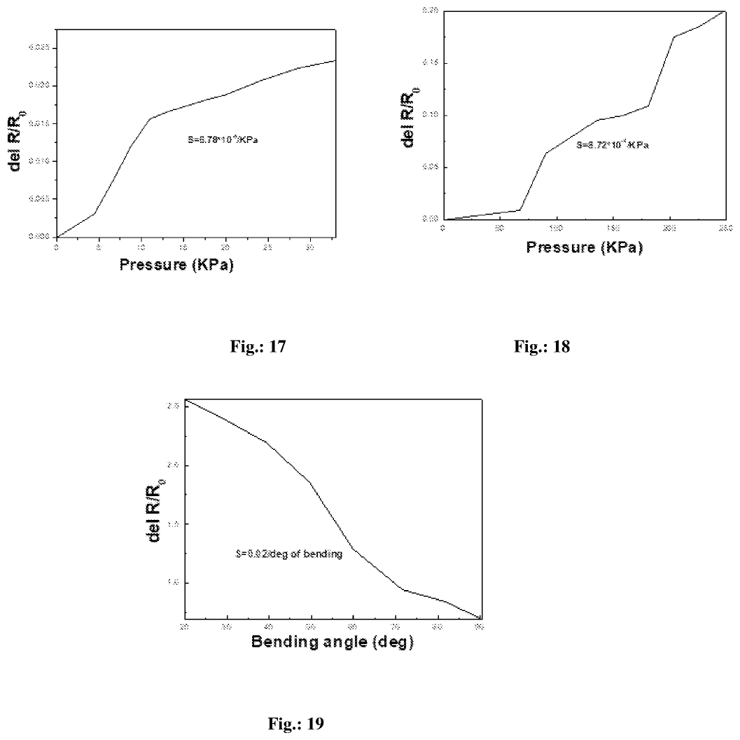

In order to test the response of the composite sensors under static force, a system containing a loading setup, a force sensor and a 3.5-digit multimeter was used (FIG. 15). Pressure sensitivity curves of the three sensors are plotted in FIGS. 16-18 and sensitivity of the sensors are calculated from the respective slopes of the sensitivity curves.

### Example-7

### Bending Angle

Angle of flexion of 1:1 ZnO:Graphene strain sensor was subjected to bending angles varying between 20 and 900 and corresponding changes in resistance was measured. Sensitivity plot of bending angle is shown in FIG. 19.

### Inferences

The gauge factor and linearity of the composite strain sensors of different compositions are as follows:

| Sensor composition | Gauge Factor | Linearity (R²) |
|---|---|---|
| 0.5:1::ZnO:graphene | 21.7 | 0.976 |
| 1:1::ZnO:graphene | 182.48 | 0.967 |
| 1:0.5::ZnO:graphene | 196.03 | 0.940 |

The sensitivity and linearity of the composite pressure sensors of different compositions are as follows: Among the three strain sensors, the 1:0.5::ZnO:graphene sensor showed the highest gauge factor; while the

| Sensor composition | Sensitivity (/KPa) | Linearity (R²) |
|---|---|---|
| 0.5:1::ZnO:graphene | 1.66 × 10⁻⁴ | 0.871 |
| 1:1::ZnO:graphene | 6.78 × 10⁻⁴ | 0.873 |
| 1:0.5::ZnO:graphene | 8.72 × 10⁻⁴ | 0.934 |

0.5:1::ZnO:graphene sensor showed the highest linearity.

Among the three pressure sensors, 1:0.5::ZnO:graphene sensor showed the highest sensitivity and linearity. The 1:1::ZnO:graphene based strain sensor showed a bending angle response of 0.02/degree of bending. None of the sensors showed any signs of delamination, buckling or adherence issues, even after exposure to several loading/unloading cycles.

### Advantages of the Invention

The main advantages of the present invention are:
1. A novel process for the preparation of a graphene nanoplatelets-ZnO based flexible strain and pressure sensor.
2. Sensor is developed on PDMS—a highly stretchable and durable polymer, which renders the desired flexibility to the sensor.
3. Sensor fabrication involves a novel step of deposition of the sensing ink and the PDMS layer on glass substrate, followed by a peel-off step. This process is simple, scalable and cost-effective as it does not require conventional high-cost equipment, like CVD, lithography, inkjet printer, etc.
4. Flexibility of the proposed sensor enables its use in contoured or curved surfaces where use of conventional stiff sensors is ruled out.
5. Proposed sensor possesses high sensitivity, or gauge factor and wide measuring range.
6. The active sensing layer being embedded in the PDMS substrate, makes these sensors very rugged. They do not show any signs of peeling or buckling after several stretch/release cycles.
7. The polymer matrix and sensing element used in the proposed sensor are biocompatible, and hence these sensors can be used in the study of biomechanics.
8. These sensors can find applications in electronic skin, which are expected to be an integral part of wearable devices in the near future.
9. The invention may find applications in the fields of prosthetics, robotics and health monitoring, biomechanical monitoring, etc.
10. Combining with IoT, some common applications of these sensors may be in wearable health monitoring sensors like ECG sensor, pulse monitors, gait analysers, activity trackers; robotic surgery and kinetic sensors in gaming, etc.

1-11. (canceled)

12. A process for fabricating a flexible strain and pressure sensor based on ZnO nanoparticles-graphene nanoplatelets, the process comprising:
(a) mixing a synergistic mixture of ZnO nanoparticles having a particle size distribution from 43.8 nm to 712 nm and graphene nanoplatelets having a particle size range from 50.7 nm to 220 nm with N-methyl-2-pyrrolidone and polyurethane in a solvent;
(b) masking a glass substrate with tape and exposing a section of the glass substrate at a center of the glass substrate;
(c) dispensing a ZnO nanoparticles-graphene nanoplatelets ink on the exposed section of the glass substrate with a micropipette;
(d) spin coating and curing the ZnO nanoparticles-graphene nanoplatelets ink and repeating the spin coating and curing three times;
(e) removing the tape from the glass substrate;
(f) spin coating a polydimethyldisiloxane (PDMS) solution on the glass substrate containing the cured ZnO-graphene pattern and heating at 100° C. to form a cured PDMS layer;
(g) peeling the cured PDMS layer from the glass substrate to obtain an embedded sensing layer;
(h) flipping the cured PDMS layer and connecting copper terminals to the embedded sensing layer using silver epoxy; and
(i) pouring a final passivation layer of PDMS on the embedded sensing layer, followed by curing at 80° C. for 10 minutes.

13. The process of claim 12, wherein the ratio of ZnO to graphene in the synergistic mixture is from 0.5:1 to 1:0.5.

14. The process of claim 12, wherein the ZnO nanoparticles have an average particle size of 207.1 nm.

15. The process of claim 12, wherein the graphene nanoplatelets have an average particle size of 105.2 nm.

16. The process of claim 12, wherein solvent is dimethylformamide.

17. The process of claim 12, wherein the ZnO nanoparticles-graphene nanoplatelets ink have a viscosity from 14 mPa-s to 15 mPa-s.

18. The process of claim 12, wherein the glass substrate and the passivation layer are a polydimethylsiloxane having an elastomeric base and a silicone curing agent in a weight ratio of 10:1.

19. The process of claim 12, wherein the cured PDMS layer has a modulus value from 1.5 MPa to 2.5 MPa.

20. The process of claim 12, wherein the flexible strain and pressure sensor has a gauge factor of from 182.5 to 196 in a measurement range of 0.0 to 0.1 strain (mm/mm) with a linearity from 0.94 to 0.97.

21. The process of claim 12, wherein the flexible strain and pressure sensor has a sensitivity from 1.7×10⁻⁴/kPa to 8.7×10⁻⁴/kPa in a measurement range from 0 to 250 kPa with a linearity from 0.87 to 0.93.

22. A process for fabricating a flexible strain and pressure sensor based on ZnO nanoparticles-graphene nanoplatelets, the process comprising:
(a) mixing ZnO nanoparticles-graphene nanoplatelets in a weight ratio from 0.5:1 to 1:0.5 with polyurethane and subsequently sonicating 30 minutes to 60 minutes at room temperature to reach an optimum viscosity of 14.5 mPa-s;
(b) masking a glass substrate having a size from 25 mm×25 mm to 75 mm×25 mm with tape and exposing a section of the glass substrate having a size from 15 mm×2 mm to 50 mm×5 mm at a center of the glass substrate;
(c) dispensing from 20 μL to 100 μL of an ZnO nanoparticles-graphene nanoplatelets ink on the exposed section of the substrate with a micropipette;
(d) spin coating at a speed of 250 rpm to 2500 rpm, and acceleration time of 30 s to 60, and a control time of 50 s to 60 s, followed by heating at 60° C. for 10 minutes to 20 minutes on a hot plate;
(e) repeating the (d) three times;
(f) removing the tape from the glass substrate and spin coating a polydimethylsiloxane (PDMS) solution over the ZnO nanoparticles-graphene nanoplatelets pattern at 100 rpm to 150 rpm, an acceleration time of 5 s to 8 s, and a control time of 300 s to 360 s to yield a PDMS layer of approximately 0.4 mm thickness, followed by heating at 100° C. to 120° C. for 2 minutes to 5 minutes;
(g) curing a first layer of PDMS on the glass substrate;
(h) peeling the PDMS layer from the glass substrate to obtain an embedded sensing layer;
(i) fixing copper wire terminals to two ends of the embedded sensing thin film by silver paste for further electrical measurements; and
(j) pouring a second layer of PDMS on the embedded ZnO nanoparticles-graphene nanoplatelets to obtain a sandwich structure of the flexible strain and pressure sensor and subsequently curing the second layer at 60° C. to 80° C. for 10 minutes to 15 min to act as a passivation layer.
